(19) United States
(12) Patent Application Publication
(10) Pub. No.: US 2026/0279976 A1
(43) Pub. Date: Sep. 17, 2026

(54) Plasma Treatment Method and Secondary Battery Manufacturing Method Comprising the Same

(71) Applicant: LG Energy Solution, Ltd., Seoul (KR)

(72) Inventors: Wan Ju Kim, Daejeon (KR); Ji Hoon Lee, Daejeon (KR); Min Seok Kim, Daejeon (KR)

(73) Assignee: LG Energy Solution, Ltd., Seoul (KR)

(21) Appl. No.: 19/469,226

(22) PCT Filed: Mar. 19, 2024
(86) PCT No.: PCT/KR2024/003403

§ 371 Date: Sep. 25, 2025

(30) Foreign Application Priority Data
Mar. 30, 2023 (KR) 10-2023-0042329

(51) Int. Cl. H01M 50/105; H01J 37/32; H01M 10/04; H01M 10/42; H01M 50/186

(52) U.S. Cl. CPC H01M 50/105; H01J 37/32422; H01J 37/32449; H01M 10/0481; H01M 10/4285; H01M 50/186

(57) ABSTRACT

A secondary battery manufacturing device includes a moving stage, a plasma generator, a plasma head, and a delivery flow passage. The moving stage is configured to support a pouch and linearly move the pouch in a first direction. The plasma generator is configured to discharge a gas internally to form a plasma gas. The plasma head is configured to spray a surface of the pouch with the plasma gas generated by the plasma generator to improve pouch sealing strength after sealing. The delivery flow passage is configured to deliver the plasma gas generated by the plasma generator to the plasma head with a carrier gas.

### CROSS-REFERENCE TO RELATED APPLICATIONS

The present application is a national phase entry under 35 U.S.C. § 371 of International Application No. PCT/KR2024/003403 filed Mar. 19, 2024, which claims priority to Korean Patent Application No. 10-2023-0042329 filed Mar. 30, 2023 in the Republic of Korea, the disclosures of which are incorporated herein by reference in their entirety.

### TECHNICAL FIELD

The present disclosure relates to a method for manufacturing a pouch-type secondary battery, and more specifically, relates to a plasma treatment method that can increase a sealing strength of a pouch, and improve insulation performance of the sealing, a method for manufacturing a secondary battery, and a manufacturing device or manufacturing the same.

### BACKGROUND ART

Secondary batteries are batteries capable of repeated use through a discharging process converting chemical energy into electrical energy and a charging process converting electrical energy into chemical energy.

Secondary batteries may include nickel-cadmium (Ni—Cd) batteries, nickel-hydrogen (Ni-MH) batteries, lithium-metal batteries, lithium-ion (Li-Ion) batteries, and lithium-ion polymer batteries (Li-Ion Polymer batteries, hereinafter referred to as “LIPB”), and the like.

Lithium secondary batteries have a life cycle of about 500 cycles or more and a short charging time of about 1 to 2 hours, and are lighter to the extent of about 30% to 40% compared to nickel-hydrogen batteries, thereby enabling weight saving, and have the highest voltage (30 to 37V) unit cell among existing secondary batteries, and excellent energy densities, so that they can have characteristics optimized for mobile devices.

Lithium secondary batteries can be manufactured as pouch-type secondary batteries by encapsulating a battery cell with a pouch which is formed of an aluminum encapsulation material.

The pouch-type secondary battery may comprise a battery cell accommodated in a pouch as an encapsulating material, a lead tab electrically connected to electrode tabs of electrodes provided in the battery cell to be drawn or extended out to the outside of the pouch, and an insulating film electrically insulating the lead tab. Particularly, the pouch may perform a function of sealing the battery cell accommodated therein by heat-sealing the inner surface of the pouch with the insulating film formed on the lead tab of the battery cell, or directly heat-sealing the inner surface of the pouch with the inner surface of the pouch. The insulating film is generally a polypropylene (PP) film.

The pouch sealing performs a function of sealing a certain space accommodating an electrolyte inside the pouch. When the battery cell is repeatedly charged/discharged, gas is generated, whereby the pressure inside the pouch increases, and thus for this reason, the pouch sealing requires high strength.

Meanwhile, upon sealing the pouch by heat fusion, the polypropylene (PP) film is melted and spread to be bonded. The polypropylene film does not only bond the pouch, but also separates the metal layer of the pouch, such as aluminum, from the electrolyte, thereby preventing corrosion of the metal layer, and preventing current from flowing through the pouch and thus increasing resistance.

Korean Patent Publication No. 10-2022-0154638 (hereinafter, referred to as a “KR '638”) discloses a method of manufacturing a pouch-type secondary battery for making the sealing surface of the pouch uniform. Particularly, to expect an effect capable of maintaining the uniformity of the sealing surface even in a wide temperature range or a wide pressure range, it discloses sealing the pouch after plasma treatment.

However, according to the KR '638, only the plasma surface treatment and the uniformity of the sealing surface are considered, but the sealing strength aspect is not considered, and particularly, conditions and timing of the plasma surface treatment, and heat fusion conditions are not disclosed. Therefore, there is a need to propose specific plasma surface treatment devices and processes that can improve the sealing strength of the pouch.

The manufacturing of pouch-type secondary batteries is performed mainly for mass production rather than small quantity production, and particularly, the entire process is performed sequentially, so that it is very important to increase process efficiency, i.e., the number of good products that can be produced in unit time. Therefore, there is a need to provide plasma surface treatment devices and processes, which are easily constructed and controlled while being organically and easily integrated into the conventional pouch-type secondary battery manufacturing process and manufacturing device, and moreover, pouch-type secondary battery manufacturing devices and processes.

### DISCLOSURE

### Technical Problem

The present disclosure is intended to increase sealing strength of a pouch in a pouch-type secondary battery.

In one example of the present disclosure, it is intended to provide a manufacturing device and a manufacturing method of a pouch-type secondary battery that can be easily integrated into the conventional manufacturing device and manufacturing method of a pouch-type secondary battery.

In another example of the present disclosure, it is intended to provide a manufacturing device and a manufacturing method of a pouch-type secondary battery that can continuously and organically plasma-treat the pouch surface.

In another example of the present disclosure, it is intended to provide a pouch-type secondary battery having a sealing portion heat-sealed after plasma treatment. Through this, it is possible to significantly reduce the matter in which sealing is ruptured due to gas generated internally and thus an electrolyte is leaked, whereby it is intended to provide a pouch-type secondary battery with improved lifespan and performance.

### Technical Solution

In order to achieve the above-described object, according to one example of the present disclosure, it is possible to provide a pouch-type secondary battery manufacturing device comprising: a moving stage supporting a pouch before sealing and linearly moving the pouch in a first direction; a plasma generator discharging gas internally to form plasma; a plasma head irradiating (or spraying) the surface of the pouch with the plasma gas generated by the plasma generator to improve pouch sealing strength after sealing; and a delivery flow passage delivering the plasma gas generated by the plasma generator to the plasma head through a carrier gas.

In some examples, the plasma generator is positioned spaced apart from the plasma head, and both are connected through the delivery flow passage.

The moving stage may move linearly together with the pouch. The moving stage may be in the form of a roll, and may be provided to linearly move the pouch as it rotates.

The plasma head may be provided to be spaced apart in a second direction perpendicular to the first direction.

In some examples, the plasma head is fixed, and provided to irradiate or spray the surface of the pouch with the plasma gas downward in a vertical direction.

The moving stage may be provided to move the pouch at a constant speed.

The plasma head may be provided to irradiate the surface of the pouch moving while being supported by the moving stage with the plasma gas. In some examples, the moving stage and the plasma head are positioned to face each other. When the moving stage is a roll supporting and transferring the pouch, that is, a transfer roll, the transfer roll and the plasma head may be positioned to face each other. Therefore, smooth surface treatment may be possible as the plasma head irradiates the region where the pouch is supported with the plasma gas.

In some examples, a gas for plasma discharge and the carrier gas are continuously supplied at a constant flow rate inside the plasma generator. Through this, the flow rate of the plasma gas irradiated to the pouch surface can be controlled constantly.

In some examples, the gas discharged upon generating plasma in the plasma generator contains nitrogen (N₂).

In some examples, the carrier gas is nitrogen. That is, only a portion of the supplied nitrogen is plasma-discharged, and nitrogen radicals may be supplied to the pouch surface by undischarged nitrogen. To this end, nitrogen may flow into the plasma generator at a sufficient flow rate.

In some examples, the flow rate of nitrogen flowing into the plasma generator is 100LPM to 250LPM.

In some examples, the linear movement velocity of the pouch before sealing is 20 mm/s to 60 mm/s.

The gas for plasma discharge may be compressed-dry air (CDA), and the carrier gas may be nitrogen.

The compressed-dry air flowing into the plasma generator may have a flow rate of 0.7LPM.

Through this example, the plasma treatment intensity can be varied by adjusting the flow rate range of the supply gas and the pouch linear velocity range. Also, the plasma treatment intensity can be varied by adjusting the nitrogen flow rate range, the pouch linear velocity range, the presence or absence of CDA, and the CDA flow rate range. In addition, the plasma treatment intensity may also be adjusted through increase or decrease of the discharge power.

In some examples, the pouch surface-treated using the plasma gas is sealed through heat fusion.

In some examples, the heat fusion is performed for 1.5 seconds under 200 degrees Celsius and a pressure of 0.1 MPa.

In order to achieve the above-described objects, according to one example of the present disclosure, it is possible to provide a method for manufacturing a pouch-type secondary battery comprising: a pouch supply step of continuously moving a pouch sheet on a moving stage; a plasma surface treatment step of irradiating the surface of the pouch sheet with plasma gas generated from a plasma generator through a plasma head; a casing step of forming a pouch case together with a battery cell by molding the plasma surface-treated pouch sheet; and a pouch sealing step of sealing the pouch case through heat fusion, and characterized in that the plasma gas moves from the plasma generator to the plasma head through a carrier gas to be irradiated to the pouch sheet.

In the pouch supply step, the pouch may be supplied in the form of a roll before being cut into unit pouches. Therefore, a pouch sheet, which is continuously supplied through the pouch sheet roll, can be continuously plasma-treated. Then, in the casing step, the pouch sheet is cut into unit pouches and forming is performed.

In some examples, the plasma gas flows into the plasma head through a delivery flow passage provided between the plasma generator and the plasma head.

In some examples, a gas for plasma discharge and the carrier gas are continuously supplied at a constant flow rate inside the plasma generator. Therefore, in terms of the plasma generator, the gas supply, the plasma discharge, and the plasma gas emission may be performed simultaneously.

In addition, the plasma head may irradiate the surface of the pouch moving while being supported by the moving stage with the plasma gas and the carrier gas. As the plasma head irradiates the region where the pouch is supported on the moving stage with the plasma gas, smooth surface treatment may be performed.

The gas discharged upon generating plasma in the plasma generator may contain nitrogen (N₂). The carrier gas may be nitrogen.

In some examples, the flow rate of nitrogen flowing into the plasma generator is 100LPM to 250LPM.

In some examples, the linear movement velocity of the pouch before sealing is 20 mm/s to 60 mm/s.

In some examples, the pouch sealing step is performed within 5 minutes after the plasma surface treatment step.

In some examples, a water contact angle on the surface of the pouch sheet after the plasma surface treatment is 41 degrees to 50 degrees.

### Advantageous Effects

According to the present disclosure, in a pouch-type secondary battery, it is possible to basically increase a sealing strength of the pouch.

Through one example of the present disclosure, it is possible to provide a manufacturing device and a manufacturing method of a pouch-type secondary battery that can be easily integrated into the conventional manufacturing device and manufacturing method of a pouch-type secondary battery.

Through one example of the present disclosure, it is possible to provide a manufacturing device and a manufacturing method of a pouch-type secondary battery that can continuously and organically plasma-treat the pouch surface.

Through one example of the present disclosure, it is possible to provide a pouch-type secondary battery having a sealing portion heat-sealed after plasma treatment. Through this, it is possible to significantly reduce the matter in which sealing is ruptured due to gas generated internally and thus an electrolyte is leaked, whereby it is possible to provide a pouch-type secondary battery with improved lifespan and performance.

### DESCRIPTION OF DRAWINGS

FIG. 1 is perspective view of a conceptual diagram of a pouch-type secondary battery manufacturing device according to one example of the present disclosure;

FIG. 2 is a plan view of a unit pouch;

FIG. 3 is a manufacturing flow chart of a pouch-type secondary battery according to one example of the present disclosure;

FIG. 4 is a diagram of a pouch-type secondary battery manufacturing device according to one example of the present disclosure;

FIG. 5 illustrates water contact angle images of pouch surfaces;

FIG. 6 is a table of measured seal strength data;

FIG. 7 is a graph of measured sealing strength data;

FIG. 8 illustrates sealing strength sampling locations in a pouch; and

FIG. 9 illustrates a sampling method and dimensions in a pouch.

### DETAILED DESCRIPTION

Hereinafter, a pouch-type secondary battery manufacturing device according to one example of the present disclosure will be described in detail with reference to the attached drawings.

First, a device and a method surface-treating a pouch will be described with reference to FIG. 1.

The pouch (10) may be seated on a moving stage (20), and the moving stage (20) may be configured to linearly move the pouch in a first direction.

The pouch (10) may be linearly moved together with the moving stage (20), or only the pouch (10) may be linearly moved on the moving stage (20). Here, the pouch (10) is moved in a horizontal direction. As one example, in a state where an upper surface facing a plasma head is maintained horizontally, it is moved in the pouch longitudinal direction (pouch supply direction).

The plasma head (30) may be provided at a location spaced apart from the moving stage (20). The plasma head (30) may be provided to supply plasma gas (40) to the surface of the pouch (10). The plasma head (20) may have a width corresponding to the width of the pouch (10). Therefore, it may be configured to supply the plasma gas (40) corresponding to the entire width of the pouch (10).

The plasma head may be positioned and fixed in a second direction perpendicular to the first direction. Therefore, the plasma gas (40) may be continuously supplied from the fixed plasma head, and the pouch (10) may continuously pass through a plasma section or region where the plasma gas (40) is supplied. In this instance, the plasma surface treatment is performed on the pouch (10).

The pouch (10) forms a seal accommodating a battery cell therein. Specifically, the sheet-shaped pouch (10) is cut and formed, and the facing edge surfaces of the pouch are heat-sealed to seal the battery cell inside.

According to this example, the plasma surface treatment can be performed not only on the edge surface of the pouch that is heat-sealed and sealed, but also on the inner surface of the pouch that is in close contact with the battery cell. That is, according to this example, the pouch on which the plasma surface treatment is performed may be a pouch before sealing and simultaneously a pouch sheet before cutting and forming for forming a seal.

When the pouch sheet is subjected to plasma surface treatment, the pouch sheet can be easily plasma surface-treated continuously and automatically. Particularly, only a portion of the pouch, especially the sealing portion is not plasma surface-treated, so that the subsequent processes can be very simple. As one example, when the plasma surface treatment is performed on four edge surfaces of a square pouch, continuous plasma surface treatment is not easy.

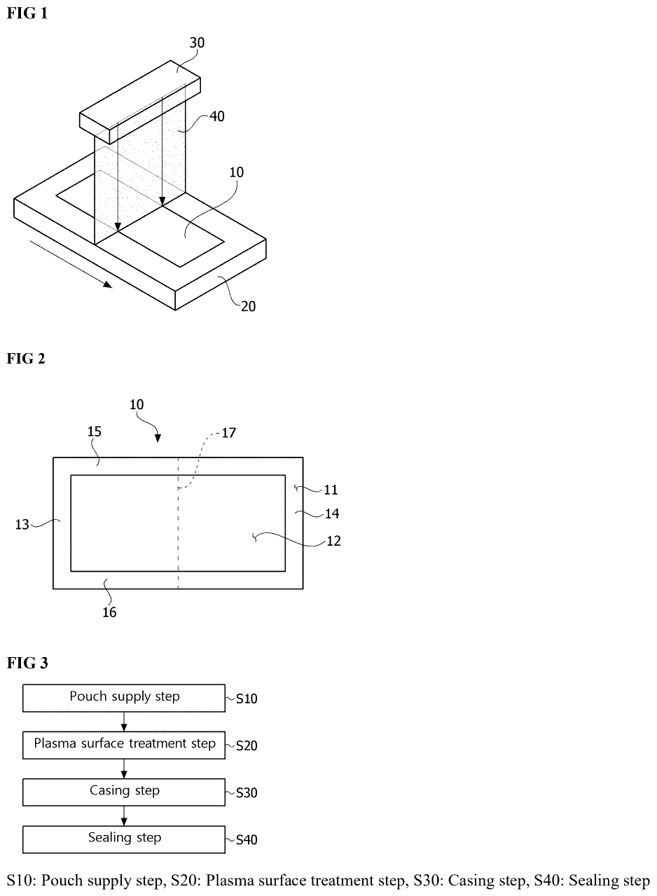

As shown in FIG. 2, a single pouch (10) forming a single pouch-type secondary battery may be cut from a pouch sheet to form a rectangular thin sheet.

The pouch sheet may be formed by providing a polypropylene layer on the outer and inner surfaces of a thin aluminum plate. That is, when an encapsulating material is formed with the pouch sheet, the polypropylene outer surface forms the outer surface of the pouch and the polypropylene inner surface forms the outer surface of the pouch, whereby the thin aluminum plate is not exposed to external air and an internal electrolyte.

As shown, the edge surfaces (13, 14, 15, 16) of the single pouch (10) may form a sealing region (11). A cell region (12) where a battery cell closely contacts and is disposed and an electrolyte is filled may be formed in the inner side region of the sealing region (12).

A folded portion (17) may be formed in the middle of the cell region (12), and after the battery cell is seated in the cell region (12) on any one of both sides of the folded portion, the left and right cell regions (12) and sealing regions (10) may be overlapped around the folded portion. Thereafter, the pouch sealing is performed through heat fusion of the sealing region (11).

In examples where there is no folded portion, the unit pouch sheet (10) shown in FIG. 2 may be an upper casing and a lower casing of a pouch casing. Since the upper casing and the lower casing are positioned to face each other, and then sealed, the sealing region (11) appears in the same aspect. However, if there is a folded portion, the sealing is unnecessary due to the folded portion, so that the sealing may be performed on three-line segments; and if there is no folded portion, the sealing may be performed on four-line segments.

If only the sealing region (11) shown in FIG. 2 is subjected to plasma surface treatment, the plasma surface treatment process becomes very complicated. First, the left and right edge surfaces (13, 14) must be intermittently plasma-treated, and then after rotating the pouch (10) 90 degrees, the upper and lower edge surfaces (15, 16) must be intermittently plasma-treated. Therefore, at least two plasma heads are needed, and the widths of the plasma heads may also be different from each other.

Ultimately, when only the sealing region (11) is subjected to plasma surface treatment, the plasma control is not easy and the device also becomes complicated. Particularly, the plasma surface treatment must be performed uniformly throughout the sealing region (11), but non-uniform plasma treatment regions may occur on the edge surfaces at the corners. This is because rotation of the pouch (10) is necessary when the plasma treatment is subjected to the entire sealing region (11). At this time, the plasma surface treatment may not be performed on some portions and the plasma surface treatment may also be overlapped on some portions.

In addition, when only the sealing region (11) is subjected to plasma surface treatment, it must be performed after cutting the sheet-shaped pouch. This is because the traveling direction of the pouch with respect to the plasma treatment device must be changed. Therefore, it may not be easy to plasma surface-treat the pouch sheet while transporting it in the roll-to-roll (R-to-R) form.

Meanwhile, according to one example of the present disclosure, only one side of the pouch corresponding to the inner surface of the pouch is plasma surface-treated, and then sealed, and the plasma surface treatment may be unnecessary for one side of the pouch corresponding to the outer surface of the pouch.

According to one example of the present disclosure, there is no need to change the position of the pouch, and particularly, the number of plasma heads can be reduced. As one example, it is possible to allow the sheet-shaped pouch to pass continuously through a single plasma head. Particularly, as shown in FIG. 2, the plasma treatment can be performed on the entire pouch without dividing it into a sealing region (11) and a cell region (12). That is, the plasma surface treatment can be performed very easily on the entire polypropylene coating layer corresponding to the inner surface of the pouch.

Ultimately, according to this example, the plasma treatment is performed on the entire one side of the pouch sheet before cutting into single pouches and before sealing, thereby enabling very effective and easy device configuration and control logic.

Hereinafter, a secondary battery manufacturing method according to one example of the present disclosure will be described in detail with reference to FIG. 3.

The manufacturing process of a pouch-type secondary battery includes an electrode process, an assembly process, and a formation process, where it can be said that this example specifically relates to the assembly process.

First, a pouch forming a seal, that is, a case of a pouch-type secondary battery may be provided (S10). That is, a pouch supply step may be performed. Here, the pouch may be a sheet-shaped pouch. As such, the pouch may be continuously moved on a moving stage using the roll-to-roll. Here, the moving stage may also be a horizontal plane-shaped stage or a roll-shaped stage. Here, the pouch sheet may be a pouch sheet roll before cutting rather than a cut pouch for manufacturing a single pouch-type battery.

The plasma surface treatment is performed on the supplied pouch sheet (S20). That is, a plasma surface treatment step may be performed. As described above, the plasma surface treatment may be performed by continuously irradiating or spraying the surface of the pouch sheet with plasma gas from a plasma head. In this instance, the plasma head may irradiate plasma gas substantially over the entire width of the pouch sheet. Therefore, as the pouch sheet passes through the plasma head at a constant speed, the plasma treatment may be performed on substantially the entire surface of the pouch sheet. Of course, the surface herein means a surface forming the inner surface of the pouch case later, the plasma treatment on the surface forming the outer surface of the pouch case later may be meaningless.

After the plasma treatment on the pouch sheet is completed, the pouch sheet is molded to form a pouch case together with the battery cell (S30). That is, a casing step may be performed. Specifically, a roll-shaped pouch sheet may be cut into unit pouches. A pouch case may be formed after the battery cell is in close contact with the cut unit pouch. At this time, to insert the battery cell, the pouch may be formed to form a space into which the battery cell is inserted. The unit pouch may be in a form where the upper case and the lower case of the pouch case are connected through a folded portion, or each of the upper case and the lower case separated from each other may also be referred to as the unit pouch.

After the pouch case, in which the battery cell is accommodated therein, is formed, the pouch case may be sealed (S40) through heat fusion. That is, a pouch sealing step may be performed. Here, the pouch sealing may be performed excluding a path through which an electrolyte may be injected into the pouch case. Then, after the electrolyte injection is performed, inlet sealing may be further performed.

Hereinafter, the plasma surface treatment method and configuration according to this example will be described in detail.

Generally, the plasma treatment technology means direct plasma. Radicals, ions, and electrons in the plasma all act on a sample, and have high energy, whereby they easily break molecular bonds and form new bonds. When this corresponds to the plasma surface treatment of the pouch, it means that the pouch is placed in the plasma generation space. That is, as shown in FIG. 1, this means that the plasma head (30) and the stage (20) perform positive electrode and negative electrode functions, respectively. The plasma gas is generated by applying an alternating current voltage between the plasma head (30) and the stage (20) and discharging the gas, and the generated plasma gas affects the pouch surface.

However, it may not be easy to integrate the direct plasma treatment technology into the pouch plasma treatment. This is because it may not be easy to provide an electrode function to the stage (20), especially the moving stage (20). This is because the moving stage moves linearly or rotates. In addition, it may not be easy to continuously supply pouches to a space where the plasma is directly generated.

According to this example, the pouch may be plasma-treated using indirect plasma rather than direct plasma. Here, the indirect plasma, unlike the direct plasma, means that the plasma generation space and the sample are located at different spaces. In other words, the indirect plasma means that the pouch and the electrode are located at separate spaces.

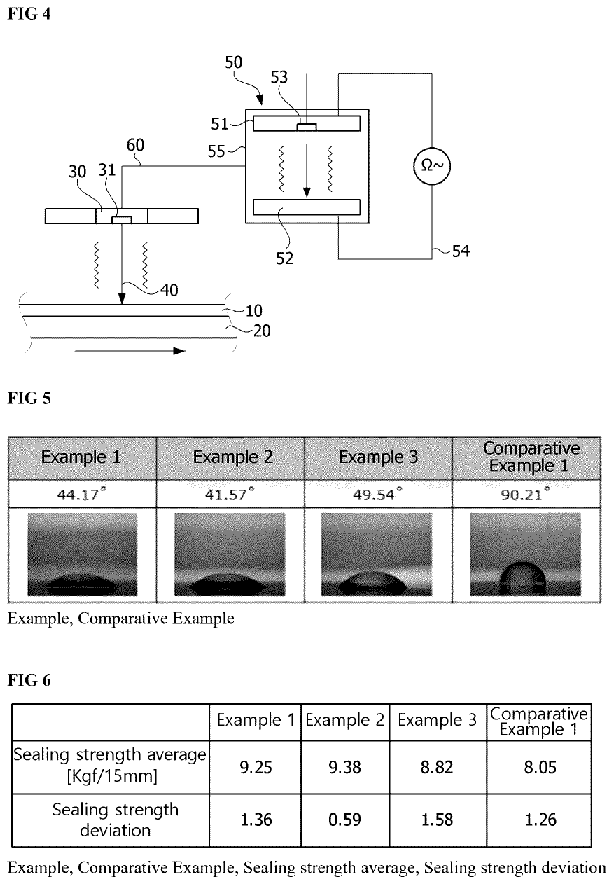

As shown in FIG. 4, the plasma generator (50) may comprise a chamber (55), and a negative electrode (51) and a positive electrode (52) facing each other may be provided in the chamber (55). The positions of the negative electrode and the positive electrode may be changed. The positive electrode (51) and the negative electrode (52) may be connected to an alternating current power supply (54) to provide power for plasma generation.

A nozzle or inlet (53) injecting gas into the chamber (55) is included. The plasma discharged gas and the carrier gas may be injected into the chamber (55) through the inlet (53). The plasma discharged gas and the carrier gas may be different gases, or may also be the same gas.

When using the indirect plasma, there may be no damage to the sample surface due to high power because the electrodes are in separate spaces, so that it is easy to turn the desired gas into plasma. However, the plasma generated by electrical energy returns to a stable state the moment the energy supply is cut off, so that a large amount of carrier gas is required to quickly deliver it to the sample. Among the ions, electrons, and radicals generated by plasma discharge, only radicals with high chemical reactivity reach the sample through the carrier gas, thereby reducing damage from physical collisions.

To supply the radicals generated in the chamber (55) to the plasma head (30), t a delivery flow passage (60) may be provided between the chamber (55) and the plasma head (30). Due to the high pressure and high flow rate of the carrier gas supplied inside the chamber (55), the plasma gas, e.g., the radicals, are supplied to the plasma head (30) through the delivery flow passage along with the carrier gas. The plasma gas supplied to the plasma head (30) may be radiated to the pouch surface along with the carrier gas.

Eventually, after the plasma treatment, radicals and the like react with the pouch surface made of polypropylene, thereby increasing the surface energy, and later, when melted due to high temperature, cohesion force occurs between different surfaces, whereby it is in a state that the sealing facilitates.

To verify the effect of improving the sealing strength of the pouch using the indirect plasma, the following examples and comparative examples were conducted.

### Example 1

Nitrogen (N₂) gas of 250LPM and CDA (compressed-dry air) of 0.7LPM were continuously sprayed with the plasma generator (50), and the gas was discharged with a power of 8.0 kW to form plasma. The plasma was sprayed through the plasma head (30) provided on the outside of the plasma generator (50) according to the gas flow rate, and the pouch (10) passed through the spray section at a linear speed of 20 mm/s. Afterwards, the pouch plasma surface-treated for 1.5 seconds under conditions of a temperature of 200 degrees Celsius and a pressure of 0.1 MPa was heat-pressed to perform pouch sealing by heat fusion. Since the surface treatment effect of plasma has changes over time, the heat-pressing was performed within 5 minutes after the plasma surface treatment. The substantial plasma discharge gas is CDA, and the substantial carrier gas is nitrogen.

### Example 2

Without using CDA, N₂ gas was supplied at 200LPM, and the linear speed of the pouch was set to 60 mm/s. Except for these, the conditions are the same as in Example 1. The nitrogen is both a plasma discharge gas and a carrier gas. A portion of the supplied nitrogen is plasma-discharged.

### Example 3

The conditions are the same as in Example 2, except that N₂ gas is supplied at 100LPM. The nitrogen is both a plasma discharge gas and a carrier gas. A portion of the supplied nitrogen is plasma-discharged.

### Comparative Example 1

The heat fusion sealing conditions are the same as in Example 1 without any plasma treatment.

Looking at Examples 1 to 3, the plasma surface treatment is changed through changes in the flow rate of the supply gas and/or the linear speed of the pouch. The higher the flow rate of the supply gas and the slower the pouch linear speed, the higher the intensity of the plasma surface treatment. In addition, the intensity of plasma surface treatment increases through the supply and the supply amount of CDA, which is easy to plasma discharge.

FIG. 5 shows water contact angles and water contact images in each of Examples 1 to 3 and Comparative Example 1. The water contact angle was measured as a method for determining the surface-treated degree of the pouch and indirectly observing the surface energy.

As shown in all the examples performing the plasma surface treatment, the water contact angles are smaller than that of Comparative Example 1. It can be expected that the sealing strength can be improved through increase of pressure-sensitive adhesive physical properties by allowing to have the water contact angle approximately in a range of 41 degrees to 50 degrees. That is, the polypropylene of the surface modified through the plasma surface treatment has polarity and generates intermolecular cohesion force, whereby the sealing strength can be improved.

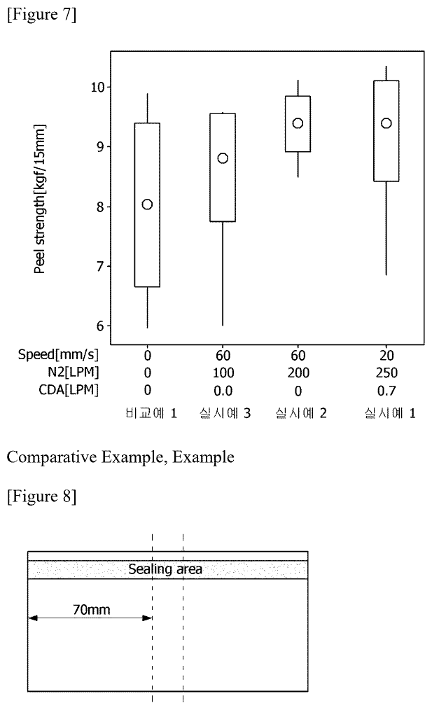

FIG. 6 is an average and deviation table of sealing strengths measured in each of Examples 1 to 3 and Comparative Example 1, and FIG. 7 is a graph of sealing strengths measured in each of Examples 1 to 3, and Comparative Example 1.

As shown in FIGS. 6 and 7, the sealing strength has been improved on average in all three examples compared to Comparative Example 1. That is, an average sealing strength improvement effect can be expected through the indirect plasma. However, in the case of Examples 1 and 3, the sealing strength deviation has increased compared to Comparative Example 1, so that it is difficult to say that the strength has been statistically improved. However, since both lower limits of the sealing strengths (peel strengths) in Examples 1 and 2 are greater than 7 kgf/15 mm, sufficient sealing strengths can be obtained.

Then, even if the CDA is excluded from the gas composition, the sealing strength increase can be obtained as can be seen in Examples 2 and 3, and particularly, the highest sealing strength and small deviation can be obtained in Example 2.

Therefore, through Examples 1 to 3, in the indirect plasma surface treatment, the sealing strength of the pouch can be obtained very effectively in the nitrogen supply flow rate range, the pouch linear velocity range, and the CDA presence and flow rate range.

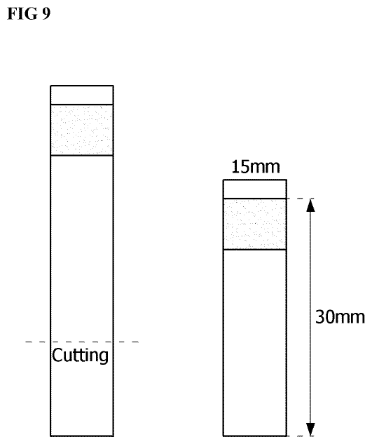

FIG. 8 shows the sampling acquisition position in the sealed pouch, and FIG. 9 shows the sampling method and sampling dimensions for measuring the sealing strength.

First, the sampling can be obtained by cutting the pouch into a dotted line portion, as shown in FIG. 8, and cutting the dotted line portion, as shown in FIG. 9. Since the pouches are overlapped up and down, the sealing strength can be measured by pulling the upper pouch in a state where the lower pouch is fixed.

The sealing strength of the sealed pouch was measured by using the tensile strength measurement function of a universal testing machine (UTM) to measure the force from the sampling to the sealing rupture. The UTM was operated to break the sealing at a constant speed of 5 mm/min, and the average of the force measured up to 8 mm after the 4.5 kgf measurement point was recorded.

### INDUSTRIAL APPLICABILITY

It is described in the Detailed Description of Disclosure.

1. A secondary battery manufacturing device comprising:
a moving stage configured to support a pouch and linearly move the pouch in a first direction;
a plasma generator configured to discharge a gas internally to form a plasma gas;
a plasma head configured to spray a surface of the pouch with the plasma gas generated by the plasma generator to improve pouch sealing strength after sealing; and
a delivery flow passage configured to deliver the plasma gas generated by the plasma generator to the plasma head with a carrier gas.

2. The secondary battery manufacturing device according to claim 1, wherein
the plasma head is spaced from the moving stage in a second direction perpendicular to the first direction.

3. The secondary battery manufacturing device according to claim 2, wherein
the plasma head is fixed, and configured to spray the surface of the pouch with the plasma gas downward in a vertical direction.

4. The secondary battery manufacturing device according to claim 3, wherein
the moving stage is configured to move the pouch at a constant speed, and the plasma head is configured to spray the surface of the pouch with the plasma gas while the pouch is being supported by the moving stage.

5. The secondary battery manufacturing device according to claim 1, wherein
the gas and the carrier gas are continuously supplied at a constant flow rate inside the plasma generator.

6. The secondary battery manufacturing device according to claim 5, wherein
the gas discharged by the plasma generator contains nitrogen (N₂).

7. The secondary battery manufacturing device according to claim 6, wherein
the carrier gas is nitrogen.

8. The secondary battery manufacturing device according to claim 7, wherein
the flow rate of the nitrogen of the gas and the carrier gas flowing into the plasma generator is 100LPM to 250LPM.

9. The secondary battery manufacturing device according to claim 8, wherein
a linear movement velocity of the pouch before sealing is 20 mm/s to 60 mm/s.

10. The secondary battery manufacturing device according to claim 5, wherein
the gas is compressed-dry air (CDA), and the carrier gas is nitrogen.

11. The secondary battery manufacturing device according to claim 10, wherein
the compressed-dry air flowing into the plasma generator has a flow rate of 0.7LPM.

12. The secondary battery manufacturing device according to claim 5, wherein
surfaces of the pouch which are surface-treated using the plasma gas are overlapped with each other, and then heat-sealed for sealing.

13. The secondary battery manufacturing device according to claim 12, wherein
the heat fusion is performed for 1.5 seconds under 200 degrees Celsius and a pressure of 0.1 MPa.

14. A method for manufacturing a secondary battery comprising:
moving a pouch sheet on a moving stage;
spraying a surface of the pouch sheet with plasma gas generated from a plasma generator through a plasma head;
forming a pouch case together with a battery cell by molding the pouch sheet after the spraying step; and
sealing the pouch case with heat fusion,
wherein the plasma gas is moved from the plasma generator to the plasma head with a carrier gas to be sprayed on the pouch sheet.

15. The method for manufacturing the secondary battery according to claim 14, wherein
a plasma discharge gas for plasma discharge and the carrier gas are continuously supplied at a constant flow rate inside the plasma generator, and
the plasma head sprays the surface of the pouch with the plasma gas and the carrier gas while the pouch is being supported by the moving stage.

16. The method for manufacturing the secondary battery according to claim 15, wherein
the plasma discharge gas discharged upon generating plasma in the plasma generator contains nitrogen (N₂).

17. The method for manufacturing the secondary battery according to claim 16, wherein
the carrier gas is nitrogen.

18. The method for manufacturing the secondary battery according to claim 17, wherein
the flow rate of the nitrogen flowing into the plasma generator is 100LPM to 250LPM.

19. The method for manufacturing the secondary battery according to claim 18, wherein
a linear movement velocity of the pouch before sealing is 20 mm/s to 60 mm/s.

20. The method for manufacturing the secondary battery according to claim 14, wherein
a water contact angle on the surface of the pouch sheet after the plasma surface treatment is 41 degrees to 50 degrees.
